(19) United States
(12) Patent Application Publication
(10) Pub. No.: US 2011/0096045 A1
(43) Pub. Date: Apr. 28, 2011

(54) DISPLAY APPARATUS

(76) Inventors: Masayuki ITO, Osaka (JP); Toshio Hata, Osaka (JP); Keiji Takasugi, Osaka (JP)

(21) Appl. No.: 12/909,138

(22) Filed: Oct. 21, 2010

(30) Foreign Application Priority Data
Oct. 22, 2009 (JP) 2009-243588

(51) Int. Cl. G09G 5/00; H01L 33/08

(52) U.S. Cl. 345/204; 257/89; 257/E33.056

(57) ABSTRACT

A display apparatus according to one embodiment of the present invention is a display apparatus comprising a surface mount-type light-emitting device having an external terminal for surface mounting; a wiring substrate where the surface mount-type light-emitting device has been mounted; a lens unit disposed opposing the surface mount-type light-emitting device; and a frame body portion disposed surrounding the lens unit.

### CROSS-REFERENCE TO RELATED APPLICATIONS

This application claims priority under 35 U.S.C. §119(a) on Patent Application No. 2009-243588 filed in Japan on Oct. 22, 2009, the entire contents of which are herein incorporated by reference.

### BACKGROUND OF THE INVENTION

1. Field of the Invention

The present invention relates to a display apparatus provided with a wiring substrate on which a surface mount-type light-emitting device has been disposed.

2. Description of the Related Art

Conventionally, display apparatuses are known in which a large screen is configured by mounting a plurality of light-emitting devices (light-emitting diodes: LEDs) on a wiring substrate. The light-emitting devices are capable of self-emission of the three primary colors of light (red: R, green: G, and B: blue), and therefore are adopted in display apparatuses in many fields.

However, display apparatuses have begun to be used in more severe environmental conditions due to expanded fields of use. For example, with light-emitting devices to be used in an outdoor illuminated display apparatus that has been installed outside, sometimes the surrounding temperature changes in a range from less than −10° C. to more than +80° C. in accordance with changes in the outdoor temperature. Also, sometimes vibration occurs at the same time as outside air pressure, heat shock, and so forth. In such a case, due to heat stress the constituent members that constitute the display apparatus repeatedly expand and contract, so structural integrity changes over time and weakens, adversely affecting optical performance. In addition, soldered portions where built-in electrical components such as drive circuits, wires and so forth are electrically connected deteriorate, so that disconnections or the like occur, and thus reliability of the display apparatus may sometimes be reduced.

FIG. 11 is a perspective view the shows an overview of a display apparatus according to a conventional example.

In this display apparatus 101 according to the conventional example, surface mount-type light-emitting devices 110 are adopted, and the display apparatus 101 includes a light-emitting device mounting substrate 120d where the surface mount-type light-emitting devices 110 have been mounted, and a drive substrate 120c where drive circuits have been mounted, and pins 121 that electrically connect the light-emitting device mounting substrate 120d to the drive substrate 120c. This sort of display apparatus is disclosed in JP 2009-76949A, for example.

The surface mount-type light-emitting devices 110 are mounted by soldering to the surface of the light-emitting device mounting substrate 120d, and the drive circuits are mounted by soldering to the surface of the drive substrate 120c. However, because the pins 121 that electrically connect the light-emitting device mounting substrate 120d to the drive substrate 120c are necessary, and the wiring path also is long, there is a risk that workability of the wiring and reliability will decrease.

Also, the surface mount-type light-emitting devices 110 that have been mounted in the display apparatus 101 are structured to directly emit light to the outside. That is, in the structure of the display apparatus 101, there is not a lens that collects light that has been emitted by the surface mount-type light-emitting devices 110. Therefore, luminous intensity is not sufficient when viewing the display apparatus 101 from the front, so although the display apparatus 101 can be used as an indoor display apparatus for indoors use, it cannot be used as an outdoor display apparatus.

Also, when using the display apparatus 101 outdoors, it is necessary to perform a waterproofing treatment by covering the front face of the surface mount-type light-emitting devices 110 with a transparent waterproof resin or the like, but because the waterproof resin becomes a light-guiding path of light that has been emitted from the surface mount-type light-emitting devices 110, the light that has been emitted from a surface mount-type light-emitting device 110 is guided to the surface of an adjacent surface mount-type light-emitting device 110, and display is performed in a state in which light is also emitted from the adjacent area. That is, in the display apparatus 101, a non-lighted portion may appear as if it emits light.

In the conventional example described above, surface mount-type light-emitting devices are applied, but many display apparatuses have also been proposed in which conventionally known molded-type LED lamps (molded-type light-emitting devices) are adopted rather than surface mount-type light-emitting devices (for example, see JP H10-233534A, JP H11-265152A, and JP 2001-290443A).

In a display apparatus in which molded-type light-emitting devices are adopted, a lead of the molded-type light-emitting devices is led out on the back side of the light-emitting device wiring substrate where the light-emitting devices are mounted, so it is not possible to dispose a drive circuit on the back face of the light-emitting device wiring substrate. That is, in a display apparatus in which molded-type light-emitting devices are adopted, it is necessary to provide a drive circuit wiring substrate where the drive circuit will be mounted separate from the light-emitting device wiring substrate.

Therefore, it is necessary to connect the light-emitting device wiring substrate and the drive circuit wiring substrate, and because the number of wires necessary for connection corresponds to the number of molded-type light-emitting devices, particularly in the case of application to a large-screen display apparatus, there is a risk that there will be a great number of wires, and as a result the workability of connections, and reliability, will decrease.

For example, in the case of a matrix display having 16 rows×16 columns of pixels, with three chips (three molded-type light-emitting devices for the three colors red, green, and blue) connected to each pixel, the display apparatus is provided with 768 light-emitting devices, and so wires corresponding to the 768 light-emitting devices are necessary between the light-emitting device wiring substrate and the drive circuit wiring substrate. Also, soldering is used to implement the wiring between the light-emitting device wiring substrate and the drive circuit wiring substrate, and this soldering takes time and labor, resulting in increased production cost. Furthermore, because there are soldering connections in many places, there is an increase in defects such as disconnections, and so there is a risk of reducing connection workability and reliability.

As a method for reducing the number of wires between the light-emitting device wiring substrate and the drive circuit wiring substrate, there is a method of lighting the light-emitting devices by time-sharing driving.

If a time-sharing driving method is applied, even in the case of a matrix display having 16 rows×16 columns of pixels, with three chips (three molded-type light-emitting devices for the three colors red, green, and blue) connected to each pixel, it is possible to allow the display apparatus to operate with 32×3 colors=96 wires. However, because time-sharing driving is being performed, the time for lighting of one light-emitting device is 1/16 of the time in the case of ordinary lighting. Therefore, in order realize the same brightness as during ordinary lighting, it is necessary to simply apply 16 times as much pulse current. Due to applying a large pulse current, the forward voltage of the light-emitting devices increases, so power consumption increases, and thus power consumption of the display apparatus is increased, and reliability is reduced.

### SUMMARY OF THE INVENTION

The present invention has been made in view of the above circumstance as described above, and it is an object thereof to provide a display apparatus in which luminous intensity when the display apparatus is viewed from the front is improved, and in which it is possible to perform display while clearly distinguishing between lit and non-lit portions, and also, the connection structure is simplified so that workability and reliability of connections are improved, and the display apparatus can be made more thin.

A display apparatus according to the present invention includes a surface mount-type light-emitting device having an external terminal for surface mounting; a wiring substrate where the surface mount-type light-emitting device has been mounted; a lens unit disposed opposing the surface mount-type light-emitting device; and a frame body portion disposed surrounding the lens unit.

According to this configuration, light that has been emitted from the surface mount-type light-emitting device is collected and thus luminous intensity in front of the lens unit is improved, so it is possible to perform display while clearly distinguishing between lit and non-lit portions, and also, the connection structure is simplified so that reliability of connections is improved, and the display apparatus can be made more thin.

Also, in the display apparatus according to the present invention, the lens unit may include a curved face portion having a curved face, and a holding portion that is extended from the curved face portion to the frame body portion and holds the curved face portion.

With this configuration, the lens unit and the frame body portion can be precisely formed in a state in which light-collecting properties are insured, so display properties (display precision) can be improved.

Also, in the display apparatus according to the present invention, a filled resin portion formed by filling a space between the surface mount-type light-emitting device and the curved face portion with synthetic resin may be provided.

With this configuration, the surface mount-type light-emitting device is covered by synthetic resin, so the surface mount-type light-emitting device is reliably protected. That is, environmental tolerance (reliability) of the surface mount-type light-emitting device is improved, and by eliminating a air layer between the surface mount-type light-emitting device and the lens unit it is possible to improve light transmission (light intensity in front of the display apparatus, that is, display properties).

Also, in the display apparatus according to the present invention, the synthetic resin may be a translucent resin.

With this configuration, translucent resin is used as the synthetic resin, so it is possible to easily realize the needed luminous intensity.

Also, in the display apparatus according to the present invention, the holding portion may include an injection inlet applied to filling of the synthetic resin, and a resin discharge outlet formed opposing the resin injection inlet.

With this configuration, the filled resin portion can be easily and precisely formed.

Also, in the display apparatus according to the present invention, the frame body portion may include a resin collection groove that collects the synthetic resin that has been discharged from the resin discharge outlet.

With this configuration, synthetic resin that overflows from the resin discharge outlet when the filled resin portion is formed can be separated from the lens unit and collected in the resin collection groove, so it is possible to stabilize the optical properties of the lens unit.

Also, in the display apparatus according to the present invention, the frame body portion may include a resin collection hole formed in communication with the resin collection groove and deeper than the resin collection groove.

With this configuration, even if an excess of the synthetic resin that forms the filled resin portion has been supplied, the synthetic resin is collected in the resin collection hole via the resin collection groove, so it is possible to reliably prevent the synthetic resin from impairing the optical properties of the lens unit (particularly the curved face portion).

Also, in the display apparatus according to the present invention, the holding portion may include a skirt portion that is extended to the side of the wiring substrate and contacts the frame body portion.

With this configuration, the lens unit and the frame body portion can be easily and precisely formed, and the filled resin portion can be easily and precisely formed.

Also, in the display apparatus according to the present invention, the skirt portion may grow larger to the outside toward the side of the wiring substrate.

According to this configuration, it is easy to mold the frame body portion and the skirt portion. That is, when the lens unit and the frame body portion are formed as a single body using a double molding method, it is possible to improve separation from the injection molding die.

Also, the display apparatus according to the present invention may further include a frame body cover portion that covers the frame body portion.

With this configuration, because the frame body cover portion covers the frame body portion, it is possible for the border of the lens unit and the frame body portion to be covered by the frame body cover portion, so it is possible to improve display precision due to making clear the distinction between lens units (curved face portions), and possible to further improve environmental tolerance.

Also, in the display apparatus according to the present invention, the frame body cover portion may cover the holding portion.

With this configuration, because the frame body cover portion covers both the frame body portion and the holding portion, it is possible to further improve display precision due to making clear the distinction between lens units (curved face portions), and possible to further improve environmental tolerance.

Also, in the display apparatus according to the present invention, the curved face portion may include an outer circumferential edge face formed in a direction intersecting the holding portion at a border with the holding portion.

With this configuration, the frame body cover portion is regulated by the outer circumferential edge face, so it is possible to prevent the frame body cover portion from being stacked on the curved face portion, and so distinguishing (display precision) of the curved face portion by the frame body cover portions can be improved.

Also, in the display apparatus according to the present invention, in the outer circumferential edge face, the side of the holding portion may be enlarged to the outside.

With this configuration, the frame body cover portion is reliably regulated by the outer circumferential edge face to precisely define the curved face portion, and thus it is possible to further improve display precision. Also, when the lens unit and the frame body portion are formed as a single body using a double molding method, it is possible to improve separation from the injection molding die.

Also, in the display apparatus according to the present invention, the lens unit may be formed by injection molding, and may include a gate-corresponding portion that is disposed at an outside position where the holding portion is extended and corresponds to a gate portion of an injection molding die, and a step formed between the gate-corresponding portion and the holding portion.

With this configuration, when the frame body cover portion that covers the frame body portion and the holding portion has been formed, even if there is some leftover resin of the gate portion in the gate-corresponding portion, it is possible to insure flatness of the frame body cover portion to the holding portion.

Also, in the display apparatus according to the present invention, an inside face opposing the wiring substrate of the curved face portion may be formed in a convex shape bulging toward the wiring substrate.

With this configuration, it is possible to prevent air bubbles from remaining in the filled resin portion after the space between the surface mount-type light-emitting device and the curved face portion has been filled with the synthetic resin.

Also, in the display apparatus according to the present invention, the frame body portion may be configured into a lens array module in which lens units are disposed in the form of a dot matrix, and the lens array module may be attached to the wiring substrate as an attachment unit.

With this configuration, strength of the frame body portion is insured, and positional precision of the lens unit relative to the surface mount-type light-emitting device is insured, so it is possible to improve reliability and display precision.

Also, in the display apparatus according to the present invention, the lens array module may be formed by a double molding method.

With this configuration, the lens array module can be formed by molding the lens unit (first side) with translucent resin and then molding the frame body portion (second side) with black resin, so the lens array module can be precisely and efficiently formed.

Also, the display apparatus according to the present invention may further include a drive circuit that drives the surface mount-type light-emitting device, and the drive circuit may be mounted only on either one of a display face of the wiring substrate where the mount-type light-emitting devices have been disposed or a back face on the opposite side.

According to this configuration, when the drive circuit is disposed only on the display face of the wiring substrate, it is possible to simultaneously mount the surface mount-type light-emitting device and the drive circuit to the wiring substrate, so productivity can be improved. Also, when the drive circuit is disposed only on the back face of the wiring substrate, it is possible to form the wiring substrate to match the outer shape of the display apparatus, and to dispose the surface mount-type light-emitting device so as to match the outer shape of the wiring substrate.

Also, in the display apparatus according to the present invention, the surface mount-type light-emitting device may include a plurality of semiconductor light-emitting elements whose emitted light colors differ from each other.

With this configuration, multi-color display is possible.

### BRIEF DESCRIPTION OF THE DRAWINGS

FIG. 1A is a plan view for describing the configuration of a display apparatus according to an embodiment of the present invention.

FIG. 1B is a diagram for describing the configuration of the display apparatus according to an embodiment of the present invention, and is a side view from the direction of arrow B in FIG. 1A.

FIG. 1C is a diagram for describing the configuration of the display apparatus according to an embodiment of the present invention, and is a side view from the direction of arrow C in FIG. 1A.

FIG. 2 is a process diagram showing a summary of production processes of the display apparatus according to an embodiment of the present invention.

FIG. 3A is a plan view for describing the configuration of surface mount-type light-emitting devices that are mounted to the display apparatus according to an embodiment of the present invention.

FIG. 3B is a diagram for describing the configuration of the surface mount-type light-emitting devices that are mounted to the display apparatus according to an embodiment of the present invention, and is a see-through side view showing relevant portions when viewed in a see-through manner from the direction of arrow B in FIG. 3A.

FIG. 4 is a partial enlarged plan view showing a partially enlarged view of a state in which the surface mount-type light-emitting devices shown in FIGS. 3A and 3B have been mounted to a wiring substrate.

FIG. 5A is a plan view for describing a lens unit applied to the display apparatus according to an embodiment of the present invention.

FIG. 5B is a diagram for describing the configuration of the lens unit applied to the display apparatus according to an embodiment of the present invention, and is a cross-sectional view at arrows B-B in FIG. 5A.

FIG. 5C is a diagram for describing the configuration of the lens unit applied to the display apparatus according to an embodiment of the present invention, and is a cross-sectional view at arrows C-C in FIG. 5A.

FIG. 6A is a plan view showing an enlarged view of a partial state of a lens array module formed by double molding lens units and a frame body portion, applied to the display apparatus according to an embodiment of the present invention.

FIG. 6B shows an enlarged view of a partial state of a lens array module formed by double molding lens units and a frame body portion, applied to the display apparatus according to an embodiment of the present invention, and is a cross-sectional view at arrows B-B in FIG. 6A.

FIG. 7A is a plan view for describing the overall configuration of the lens array module shown in FIG. 6A.

FIG. 7B is a diagram for describing the overall configuration of the lens array module shown in FIG. 6A, and is a see-through side view showing relevant portions when viewed in a see-through manner from the direction of arrow B in FIG. 7A.

FIG. 8A is an illustration of a state in which, in a production process of the display apparatus according to an embodiment of the present invention, a wiring substrate to which a lens array module has been attached is attached to a case, and a filling resin portion has been formed by filling a space between the surface mount-type light-emitting devices and the lens units with translucent resin, this illustration being a schematic side view that schematically shows the state of a side face.

FIG. 8B is an illustration of a state in which, in a production process of the display apparatus according to an embodiment of the present invention, a wiring substrate to which a lens array module has been attached is attached to a case, and a filling resin portion has been formed by filling a space between the surface mount-type light-emitting devices and the lens units with translucent resin, this illustration being an enlarged cross-sectional view that shows an enlarged view of the area of reference sign B in FIG. 8A.

FIG. 9A is an illustration of a state in which, in a production process of the display apparatus according to an embodiment of the present invention, a frame body cover portion has been formed, this illustration being a schematic side view that schematically shows the state of a side face.

FIG. 9B is an illustration of a state in which, in a production process of the display apparatus according to an embodiment of the present invention, a frame body cover portion has been formed, this illustration being an enlarged cross-sectional view that shows an enlarged view of the area of reference sign B in FIG. 9A.

FIG. 10A is an illustration of a state in which, in a production process of the display apparatus according to an embodiment of the present invention, a visor portion has been attached, this illustration being a schematic side view that schematically shows the state of a side face.

FIG. 10B is an illustration of a state in which, in a production process of the display apparatus according to an embodiment of the present invention, a visor portion has been attached, this illustration being an enlarged cross-sectional view that shows an enlarged view of the area of reference sign B in FIG. 10A.

FIG. 11 is a perspective view the shows an overview of a display apparatus according to a conventional example.

### DESCRIPTION OF THE PREFERRED EMBODIMENTS

Hereinafter, an embodiment(s) of the present invention will be described based on the accompanying drawings.

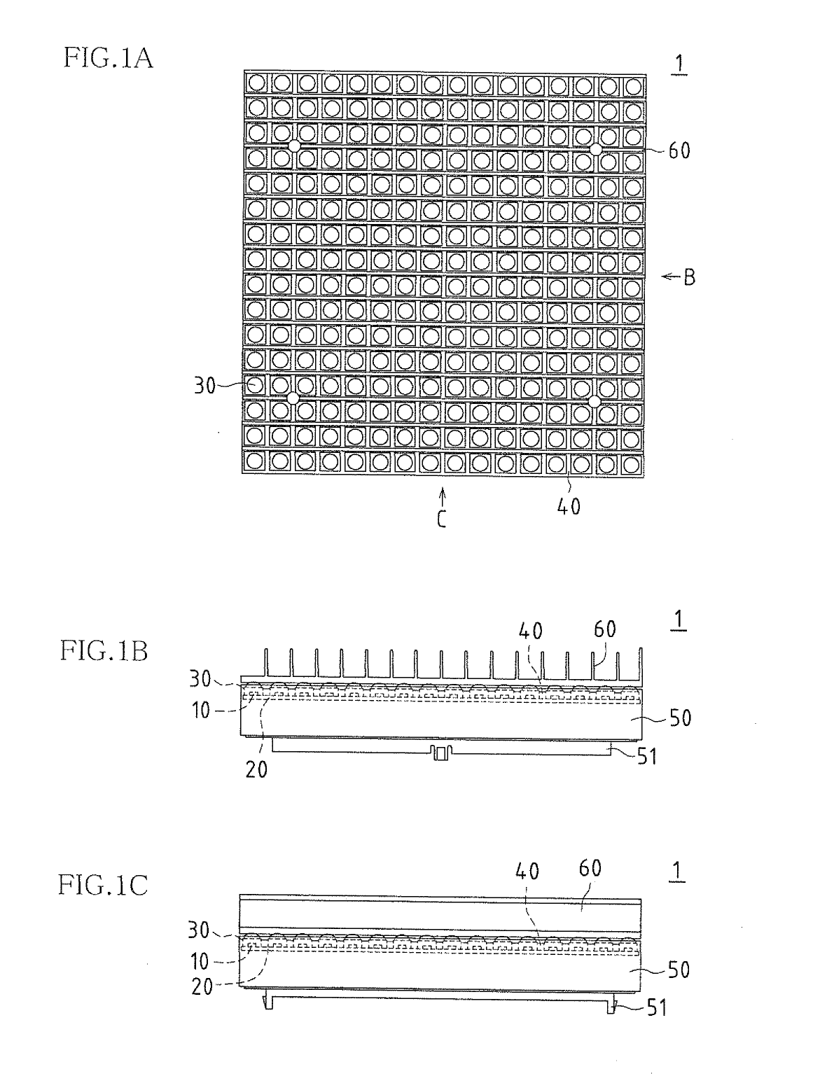

FIGS. 1A to 1C illustrate a display apparatus according to an embodiment of the present invention, where FIG. 1A is a plan view, FIG. 1B is a side view viewed from the direction of arrow B in FIG. 1A, and FIG. 1C is a side view viewed from the direction of arrow C in FIG. 1A.

The display apparatus 1 according to the present embodiment is provided with surface mount-type light-emitting devices 10 that are surface mount-type light-emitting devices, a wiring substrate 20 where the surface mount-type light-emitting devices 10 have been mounted, lens units 30 that have been disposed in front of the surface mount-type light-emitting devices 10, and a frame body portion 40 disposed surrounding the circumference of the lens unit 30. The wiring substrate 20 is attached to a case 50, and visor portions 60 are disposed on the front side of the lens units 30. The case 50 is provided with an engaging portion 51 that allows easy attachment to an electronic device where the display apparatus 1 is to be installed.

In the present embodiment, the surface mount-type light-emitting devices 10 are disposed in the form of a dot matrix having 16 vertical surface mount-type light-emitting devices 10 (16 rows) and 16 horizontal surface mount-type light-emitting devices 10 (16 columns), such that a total of 256 surface mount-type light-emitting devices 10 are mounted to the wiring substrate 20. Also, 16 visor portions 60 are disposed corresponding to the 16 rows in the vertical direction.

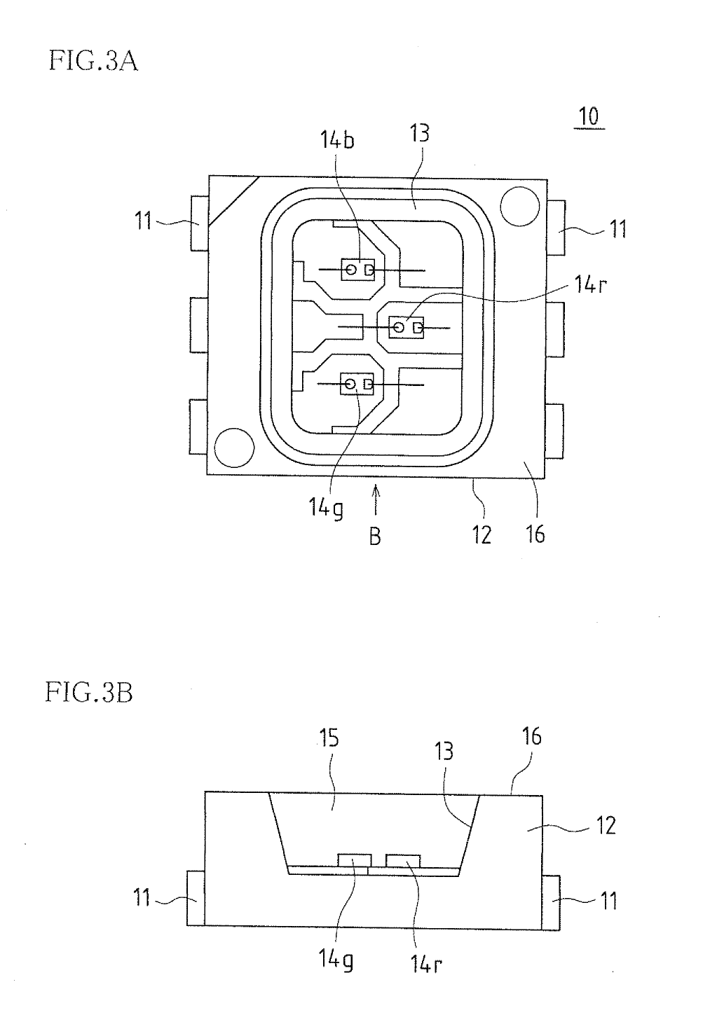

As described above, the display apparatus 1 according to the present embodiment is provided with the surface mount-type light-emitting devices 10 that have external terminals 11 (see FIGS. 3A and 3B) for surface mounting, and the wiring substrate 20 where the surface mount-type light-emitting devices 10 have been mounted, and is also provided with the lens units 30 that have been disposed opposing the surface mount-type light-emitting devices 10, and the frame body portion 40 disposed surrounding the lens units 30.

Accordingly, in the display apparatus 1, luminous intensity in front of the lens units 30 is improved by collecting light that has been emitted from the surface mount-type light-emitting devices 10, so display can be performed while clearly distinguishing between lit and non-lit portions, and also, the connection structure is simplified so that workability and reliability of connections (mounting) are improved, and the display apparatus can be made more thin.

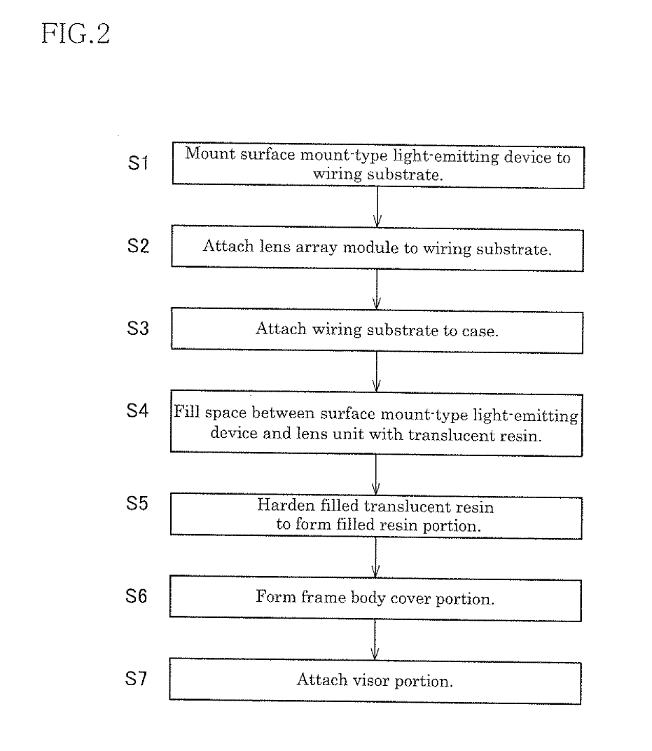

FIG. 2 is a process diagram showing a summary of production processes of the display apparatus according to the embodiment of the present invention.

The display apparatus 1 according to the present embodiment is produced with the following steps S1 to S7 as main production processes.

Step S1:

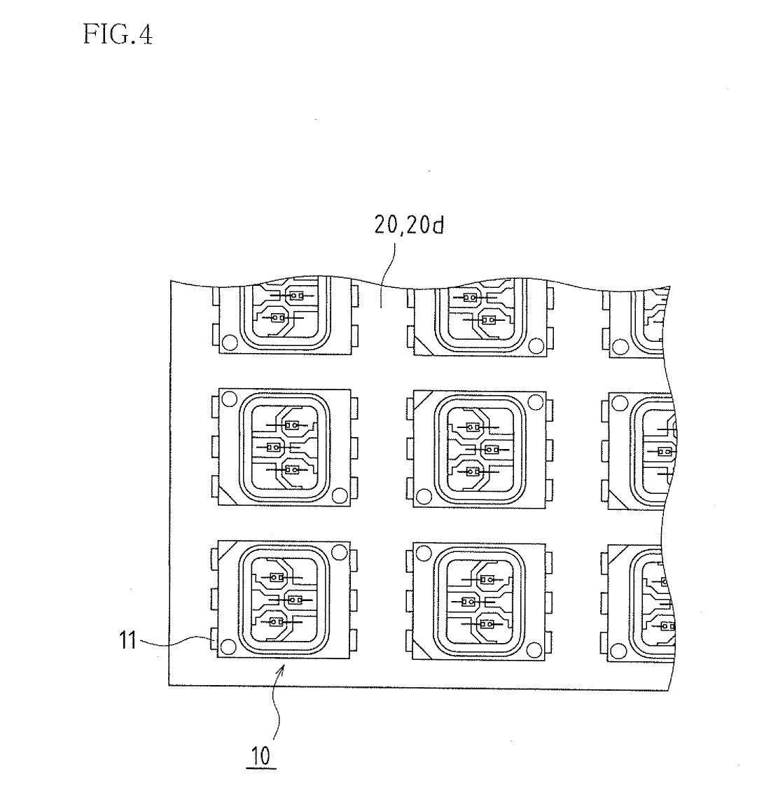

Mount the surface mount-type light-emitting devices 10 (see FIGS. 3A and 3B described below) to the wiring substrate 20 (see FIG. 4 described below).

Step S2:

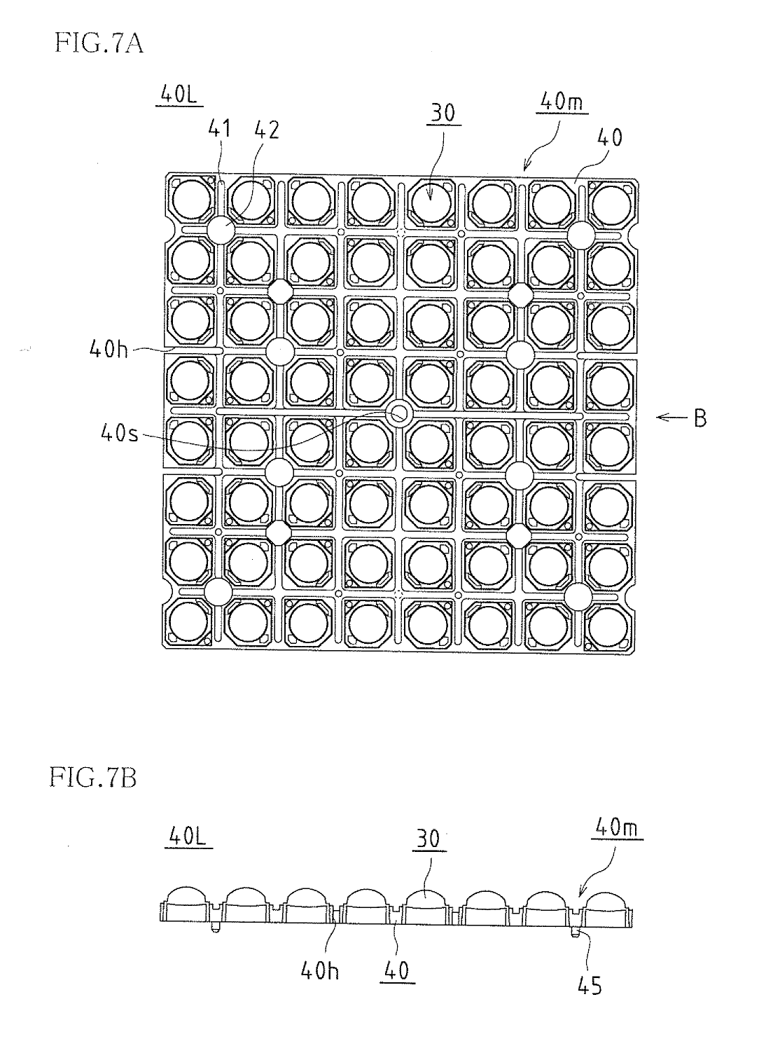

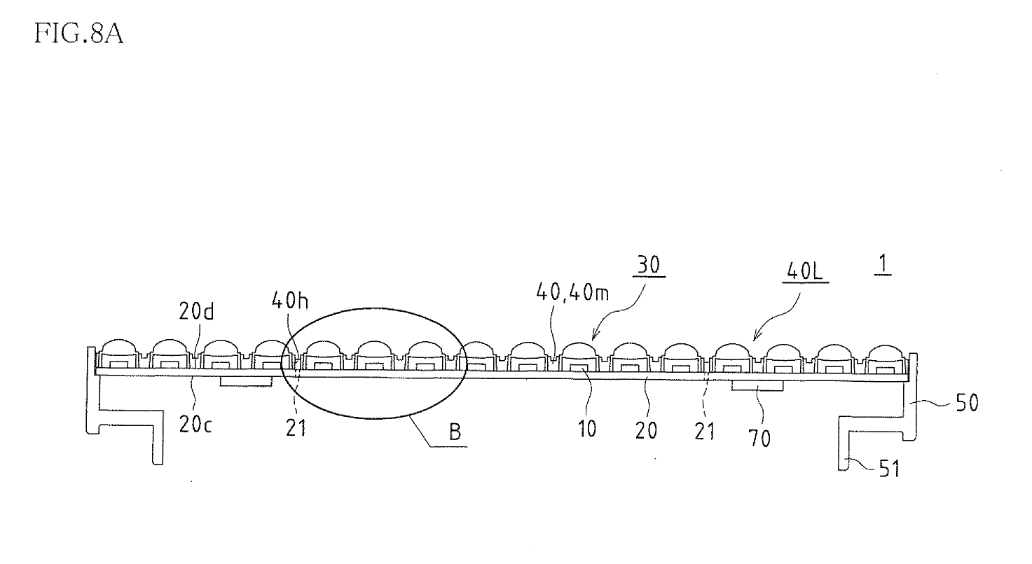

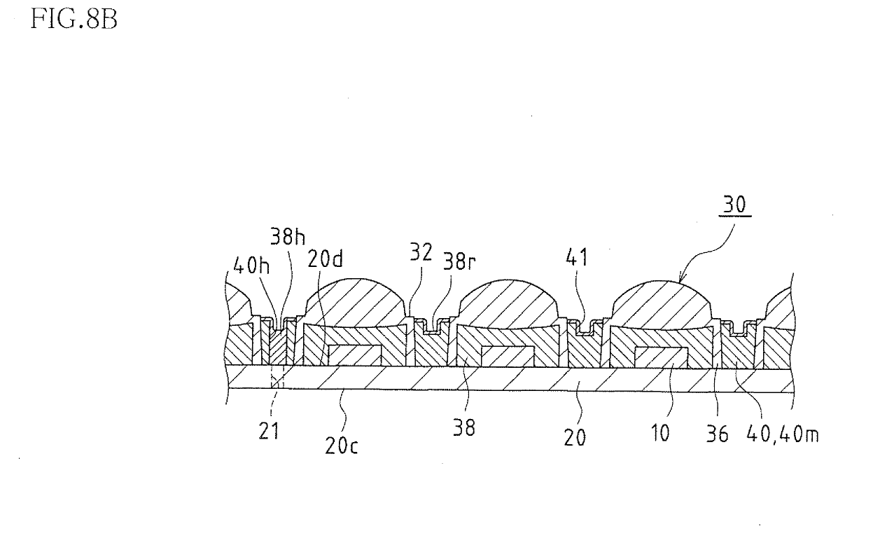

Attach a lens array 40L (lens array module 40m: see FIGS. 7A and 7B described below) to the wiring substrate 20 (see FIGS. 8A and 8B described below). The lens array module 40m is formed at an appropriate size as an attachment unit to the frame body portion 40, and is attached to the wiring substrate 20.

Step S3:

Attach the wiring substrate 20 to the case 50 (see FIGS. 8A and 8B).

Step S4:

Fill the space between the surface mount-type light-emitting devices 10 and the lens units 30 with translucent resin (synthetic resin: see FIGS. 8A and 8B).

Step S5:

Harden the filled translucent resin to form filled resin portions 38 (see FIGS. 8A and 8B).

Step S6:

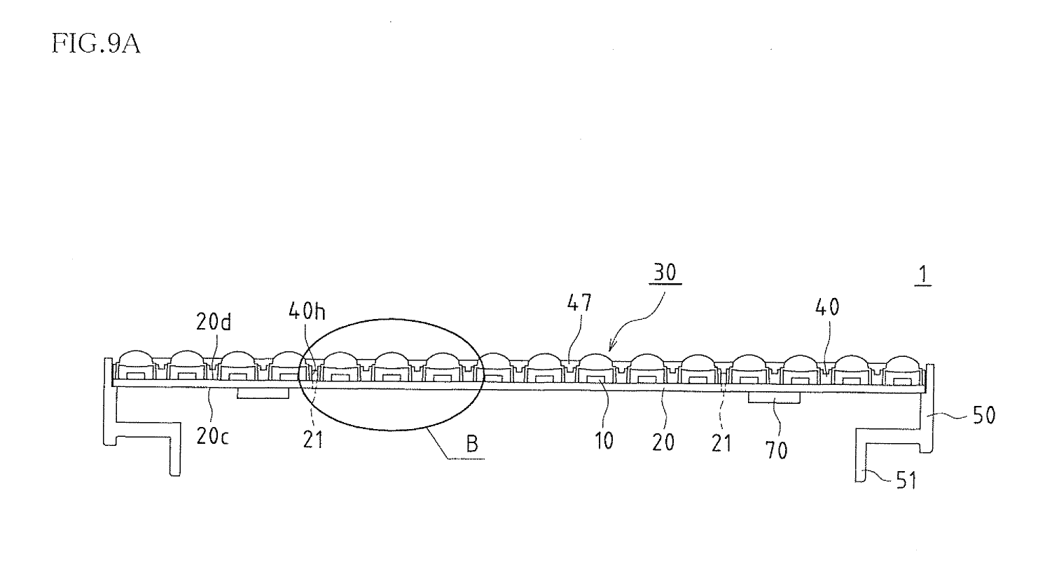

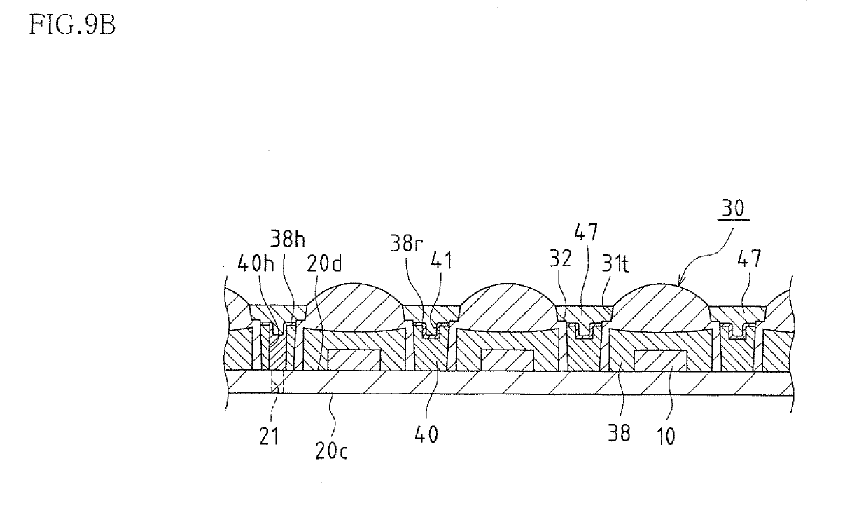

Form frame body cover portions 47 (see FIGS. 9A and 9B described below)

Step S7:

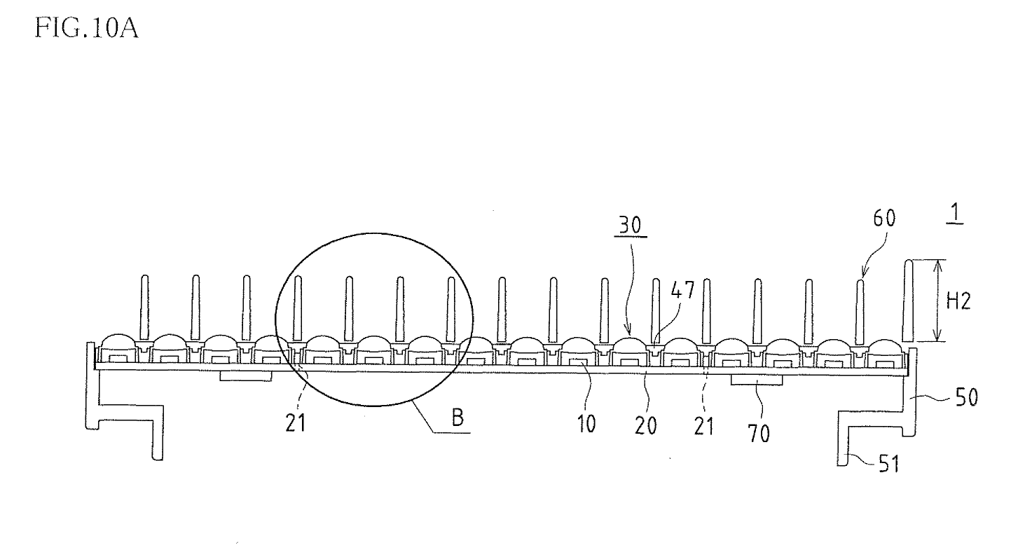

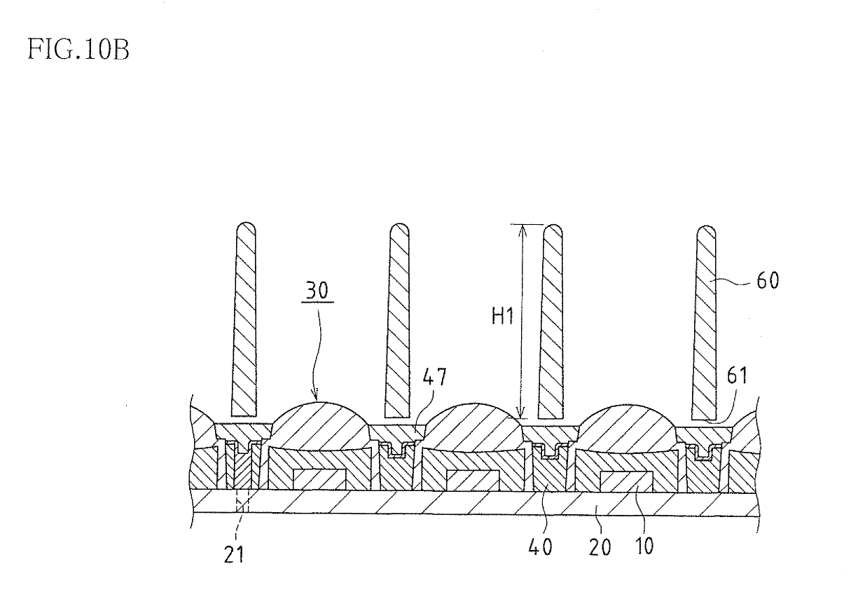

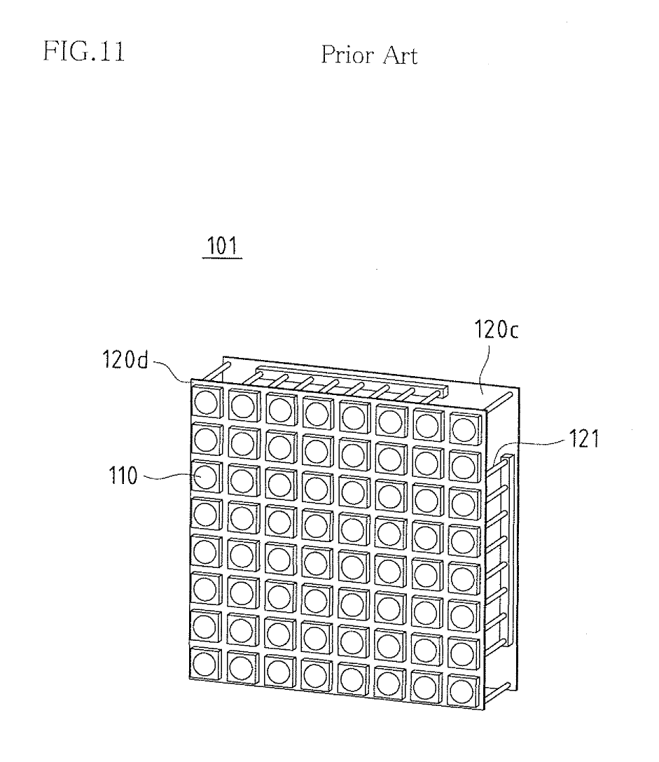

Attach visor portions 60 (see FIGS. 10A and 103 described below).

FIGS. 3A and 3B illustrate surface mount-type light-emitting devices mounted to the display apparatus according to the embodiment the present invention, where FIG. 3A is a plan view and FIG. 3B is a see-through side view showing relevant portions when viewed in a see-through manner from the direction of arrow B in FIG. 3A.

The surface mount-type light-emitting devices 10 have the external terminals 11 for surface mounting. Also, each surface mount-type light-emitting device 10 is provided with a package portion 12 that has been formed in an appropriate shape, and a concave portion 13 that has been formed in the package portion 12. Mounted to the concave portion 13 are a semiconductor light-emitting element 14r that emits red (R) light, a semiconductor light-emitting element 14g that emits green (G) light, and a semiconductor light-emitting element 14b that emits blue (B) light.

In the case of a road display (particularly when it is necessary to arouse attention using text, for example), the color orange or red is often used for the color of text, in consideration of visibility and ability to arouse attention. Ordinarily, the color orange is generated by mixing the colors red and green. Accordingly, it is possible to improve visibility by disposing the color red in the center. In the surface mount-type light-emitting device 10 according to the present embodiment, improved visibility is achieved by disposing the semiconductor light-emitting element 14r in the center, and disposing the semiconductor light-emitting element 14g and the semiconductor light-emitting element 14b on respective sides of the semiconductor light-emitting element 14r.

The semiconductor light-emitting element 14r, the semiconductor light-emitting element 14g, and the semiconductor light-emitting element 14b are mounted to a bottom face of the concave portion 13 in the state of chips obtained by dividing a semiconductor substrate, and are connected to the external terminals 11 via wiring, for example. The concave portion 13 is filled with a translucent resin portion 15, and thus the semiconductor light-emitting element 14r, the semiconductor light-emitting element 14g, and the semiconductor light-emitting element 14b are protected from the external environment. In this example, one each of the semiconductor light-emitting element 14r, the semiconductor light-emitting element 14g, and the semiconductor light-emitting element 14b are shown, but a plurality of each can be disposed.

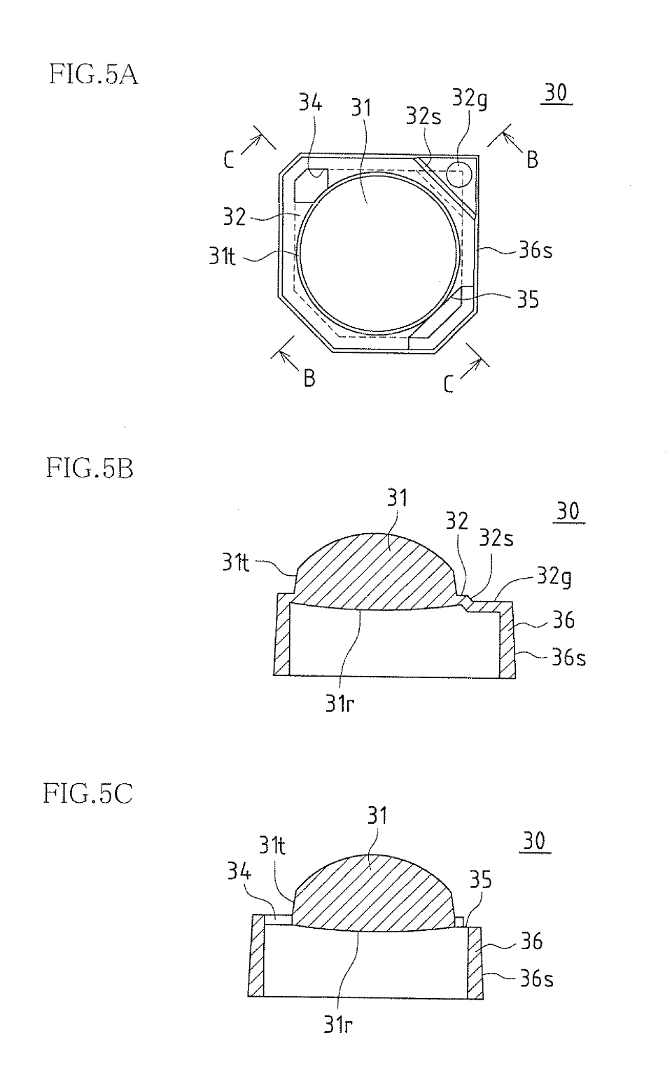

As shown, a rectangular shape is adopted for the opening of the concave portion 13, so it is possible to cause a light-emitting pattern to grow wider in the lateral direction. With this configuration, it is possible to cause the light-emitting pattern to grow wider in the lateral direction than when a circular shape is adopted. Also, by adopting a rectangular shape for the opening of the concave portion 13, it is possible to improve light-guiding for a holding portion 32 (see FIGS. 5A to 5C) that has a rectangular shape, and so it is possible to improve light intensity of a curved face portion 31, thus improving light extracting efficiency.

A similar shape to that of the curved face portion 31 (see FIGS. 5A to 5C) of the lens unit 30 can also be adopted as the shape of the opening of the concave portion 13. That is, by making the shape of the opening of the concave portion 13, which defines the light-emitting pattern, oppose the outer shape of the curved face portion 31, it is possible to reduce loss of optical coupling between the surface mount-type light-emitting device 10 (the shape of the opening of the concave portion 13) and the curved face portion 31.

Also, a black portion 16 is formed on the surface (outside of the surface of the concave portion 13) of a package portion 12, thus improving recognition (identification) of light emitted from the concave portion 13. An appropriate shape can be adopted for the package portion 12, as long as the package portion 12 can be surface-mounted to the wiring substrate 20. In FIGS. 3A and 3B, the surface of the package portion 12 is shown in a flat state, but for example, a configuration can also be adopted in which the translucent resin portion 15 has some kind of lens properties (a convex shape) on the inside of the black portion 16.

As described above, in the surface mount-type light-emitting devices 10 mounted to the display apparatus 1, the plurality of semiconductor light-emitting elements 14r, semiconductor light-emitting elements 14g, and semiconductor light-emitting elements 14b that emit different colors of light from each other are provided. Accordingly, the display apparatus 1 is capable of performing multi-color display. That is, one group of a semiconductor light-emitting element 14r, a semiconductor light-emitting element 14g, and a semiconductor light-emitting element 14b can be used to configure one pixel that performs multi-color display.

FIG. 4 is a partial enlarged plan view showing a partially enlarged view of a state in which surface mount-type light-emitting devices as shown in FIGS. 3A and 3B have been mounted to a wiring substrate.

Because the surface mount-type light-emitting devices 10 have the external terminals 11 for surface mounting, the surface mount-type light-emitting devices 10 can be placed as-is on the surface (a display face 20d) of the wiring substrate 20, and mounted (connected) thereto. Note that in consideration of legibility, FIG. 4 shows an enlarged view of only part (the disposed state of the surface mount-type light-emitting devices 10 near an end portion of the wiring substrate 20) of the wiring substrate 20 (the display face 20d).

Because the surface mount-type light-emitting device 10 is a surface mount-type, the height of the surface mount-type light-emitting device 10 at the wiring substrate 20 is the height of the package portion 12 of the surface mount-type light-emitting device 10. Accordingly, thickness can be reduced along the display face 20d of the wiring substrate 20.

The height of a molded-type LED lamp (molded-type light-emitting device) generally adopted in a conventional display apparatus is ordinarily 24 mm, because it is necessary to consider lead length. Accordingly, the height from the substrate surface when a molded-type LED lamp has been mounted to the wiring substrate 20 is 14 mm, obtained by subtracting 10 mm of lead length. On the other hand, the height of the surface mount-type light-emitting device 10 is set to 1.4 mm, for example. Accordingly, the height from the substrate surface when the surface mount-type light-emitting device 10 has been mounted to the wiring substrate 20 can be set to 1.4 mm. That is, the thickness of the display apparatus 1 can be reduced by adopting the surface mount-type light-emitting devices 10.

The weight of a molded-type LED lamp is, for example, 0.28 g (grams), while the weight of the surface mount-type light-emitting device 10 is, for example, 0.025 g (grams). Accordingly, by adopting the surface mount-type light-emitting devices 10, it is possible for the weight from the surface mount-type light-emitting devices 10 to be 1/10th of the weight in a conventional example. That is, by adopting the surface mount-type light-emitting devices 10, it is possible to reduce the weight of the display apparatus 1. Also, because reduced cost can be realized, when the display apparatus 1 is adopted in a road information display apparatus, it is possible to lower construction costs related to road construction.

The plan view shape of the wiring substrate 20 is, for example, a 160 mm×160 mm rectangle (see FIGS. 1A to 1C), and the thickness of the wiring substrate 20 is, for example, 1 mm. Also, the surface mount-type light-emitting devices 10 that have been disposed on the display face 20d in the form of a 16 row×16 column dot matrix are disposed at a pitch of 10 mm in the vertical direction and 10 mm in the horizontal direction. Note that the arrangement of the surface mount-type light-emitting devices 10 is not limited to the form of a dot matrix; an arbitrary pattern can be adopted according to the display specification of the display apparatus in which the surface mount-type light-emitting devices 10 will be applied.

The wiring substrate 20 has a wiring pattern (not shown) for arranging and fixing (connecting) the surface mount-type light-emitting devices 10. That is, the external terminals 11 of the surface mount-type light-emitting devices 10 are electrically and mechanically connected to the wiring substrate 20 (wiring pattern) by electrically conductive material such as solder. Also, drive circuits 70 (see FIGS. 8A and 8B) that supply power via the wiring pattern to the surface mount-type light-emitting devices 10 are mounted to a back face 20c (see FIGS. 8A and 8B) on the opposite side as the display face 20d.

The wiring substrate 20 preferably has high mechanical strength and is deformed little by heat. Specifically, a printed substrate employing insulating synthetic resin, ceramic, glass, aluminum alloy, or the like, that is, a rigid substrate, can be suitably used.

The display face 20d is disposed corresponding to the display face of the display apparatus 1. Accordingly, in order to improve contrast, moisture-proofing, and insulation, it is preferable that the wiring substrate 20 is formed with a substantially black resin having damp-proofing properties. Also, the substantially black resin can be applied to the surface (display face 20d) of the wiring substrate in the form of a solder resist or a marking ink.

FIGS. 5A to 5C illustrate a lens unit applied to the display apparatus according to the embodiment of the present invention, where FIG. 5A is a plan view, FIG. 5B is a cross-sectional view at arrows B-B in FIG. 5A, and FIG. 5C is a cross-sectional view at arrows C-C in FIG. 5A.

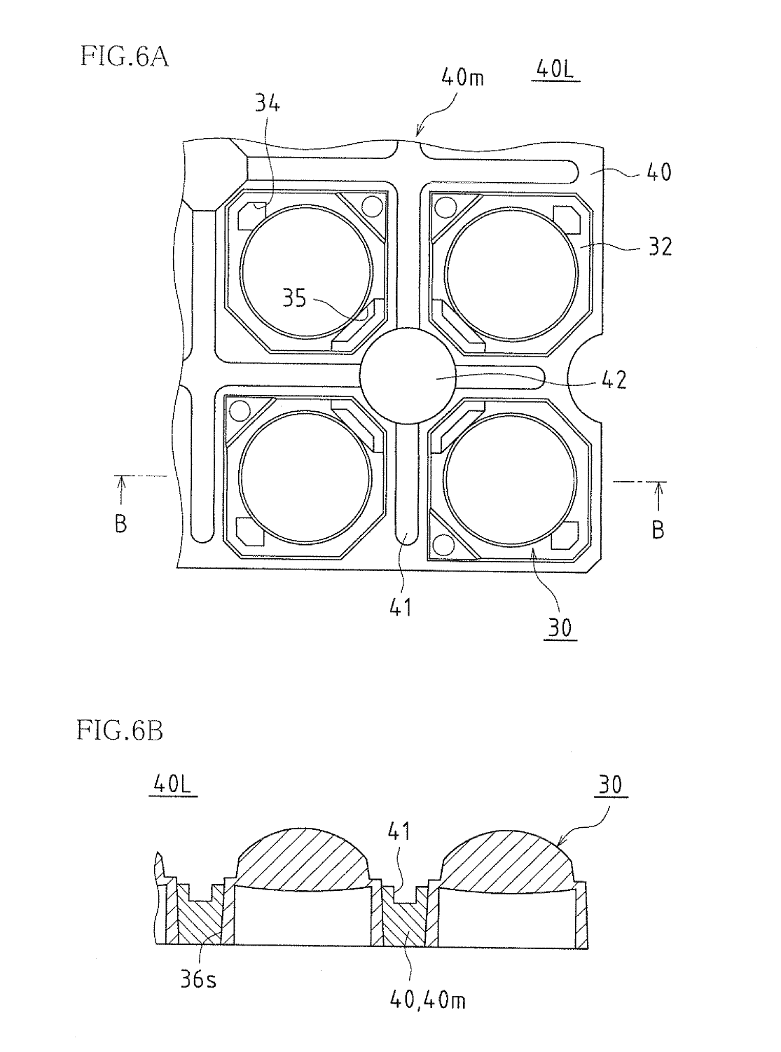

The lens unit 30 according to the present embodiment is provided with the curved face portion 31 (curved face portion 31 having a curved face) that is formed as a convex lens and has light-collecting properties, and a holding portion 32 that is extended from the curved face portion 31 to the frame body portion 40 (see FIGS. 6A and 6B), and holds the curved face portion 31. Accordingly, in the display apparatus 1, it is possible to form the lens units 30 and the frame body portion 40 with high precision in a state in which light-collecting properties are insured, so display properties (display precision) can be improved.

The holding portion 32 is provided with a skirt portion 36 that is extended to the side of the wiring substrate 20 and makes contact with the frame body portion 40 (see FIGS. 6A and 6B). Accordingly, it is possible to easily and precisely form the lens units 30 and the frame body portion 40, and it is possible to easily and precisely form the filled resin portions 38 (see FIGS. 8A and 8B).

Also, the skirt portion 36 is configured to become larger to the outside toward the side of the wiring substrate 20 relative to the side of the holding portion 32. That is, a surface 36s of the skirt portion 36 is inclined so as to widen from the holding portion 32 toward the wiring substrate 20. Accordingly, it is easy to form the frame body portion 40 and the skirt portion 36. That is, when forming the lens unit 30 and the frame body portion 40 as a single body using a double molding method, it is possible to improve separation from an injection molding die. The inclination angle of the surface 36s is set to two degrees.

The skirt portion 36 (lens unit 30), in consideration of adaptability to the frame body portion 40, is made frame-like, and is appropriately flattened (chamfered) in order to make orientation clear. The surface mount-type light-emitting device 10 is disposed on the inside of the skirt portion 36, and by filling with translucent resin (synthetic resin), the filled resin portion 38 is formed (see FIGS. 8A and 8B). The skirt portion 36 is desirably formed on all sides, but this is not a limitation. That is, any configuration is acceptable as long as the skirt portion 36 can be positioned relative to the frame body portion 40.

The lens material of the lens unit 30 is a polycarbonate resin containing a UV-absorbing agent. Accordingly, it is possible to prevent UV rays included in outside light from being incident on the surface mount-type light-emitting device 10 (see FIGS. 8A and 8B) disposed within the lens unit 30. Phenyl salicylate is applied as the UV-absorbing agent.

Resin containing a UV-absorbing agent is formed by mixing and dispersing the UV-absorbing agent in polycarbonate resin used as translucent resin material. As the UV-absorbing agent, it is possible to apply various organic UV-absorbing agents, such as salicylates, triazines, benzophenones, and cyanoacrylates.

As the lens material, it is possible to use a resin material on which a molding process can be performed, such as an acrylic or polycarbonate. Acrylic has excellent weather resistance, but poor impact resistance and heat resistance, and moreover, has a refractive index of 1.49, which is less than the refractive index of 1.59 for polycarbonate, so when attempting to have the same light-collecting properties (lens properties), lens thickness is greater than in the case of polycarbonate.

Polycarbonate has excellent impact resistance and heat resistance, but poor weather resistance, because problems occur such as a decrease in transmittance and yellowing due to UV rays included in sunlight. There is also a weather-resistant type of polycarbonate in which a UV-absorbing agent is added in order to improve weather resistance. In the present embodiment, as described above, a weather-resistant type of polycarbonate is applied.

The curved face portion 31 has a diameter of 6 mm, a height of 5.74 mm (including the skirt portion 36), and a lens thickness of 2.9 mm. An inside face 31r opposing the wiring substrate 20 of the curved face portion 31 has a convex shape protruding towards the wiring substrate 20.

The holding portion 32 is provided with a resin injection inlet 34 applied as an injection inlet when filling translucent resin (the filled resin portion 38) as synthetic resin, and a resin discharge outlet 35 formed opposing the resin injection inlet 34. By injecting the translucent resin from the resin injection inlet 34 and discharging excess translucent resin that has been supplied from the resin discharge outlet 35, air can be eliminated from inside (the inner portion where the filled resin portion 38 is to be formed) of the lens unit 30, so that it is possible to easily and precisely form the filled resin portion 38 without mixing in air bubbles. Accordingly, it is desirable that the resin injection inlet 34 and the resin discharge outlet 35 are disposed at positions opposing each other in the horizontal plane of the holding portion 32.

It is desirable that the holding portion 32 is formed like a brim in the direction intersecting the optical axis of the curved face portion 31 which is round in plan view, and has a polygonal shape having at least four corner portions in plan view. By making the holding portion 32 a polygon having at least four corners, it is possible to dispose the resin injection inlet 34 and the resin discharge outlet 35 so as to oppose each other at corner portions disposed on a diagonal line, and thus precise forming is possible.

If the holding portion 32 is made circular in plan view, it is difficult to cause the resin injection inlet 34 and the resin discharge outlet 35 to precisely oppose each other, and even once formed, placement is awkward, and thus it is not possible to precisely execute injection and discharge of the synthetic resin. Note that if the skirt portion 36 is disposed in a state in which the holding portion 32 will not be disposed, it will be substantially impossible to form the resin injection inlet 34 and the resin discharge outlet 35.

The resin injection inlet 34 has a size corresponding to the size of a nozzle of an injector that injects the synthetic resin. The resin discharge outlet 35 is configured with a shape such that it is possible to efficiently discharge air that has been mixed into the synthetic resin, by being made wider than the resin injection inlet 34.

In the present embodiment, the lens unit 30 is formed by injection molding, and is provided with a gate-corresponding portion 32g that is disposed at an outside position where the holding portion 32 is extended and corresponds to a gate portion of the injection molding die, and a step 32s that has been formed between the gate-corresponding portion 32g and the holding portion 32.

Accordingly, in the display apparatus 1, when the frame body cover portions 47 (see FIGS. 9A and 9B) that cover the frame body portion 40 and the holding portions 32 have been formed, even if there is some leftover resin of the gate portion of the die in the gate-corresponding portions 32g, it is possible to insure flatness of the frame body cover portions 47 to the holding portions 32.

Supposing that there is not a step 32s, if there is leftover resin in the gate-corresponding portions 32g (gate leftover resin), when the frame body cover portions 47 are stacked and formed in the area of the gate-corresponding portions 32g, the frame body cover portions 47 stacked on the gate-corresponding portions 32g bulge upward, and so the surface of the frame body cover portions 47 is not in a flat state, so there is a risk of uneven contrast, uneven display, and so forth.

By providing the step 32s, if the amount of protrusion of leftover resin in the gate-corresponding portion 32g is less than the height of the step 32s, when the frame body cover portion 47 has been formed, flatness of the surface of the frame body cover portion 47 can be maintained, and so display properties can be improved. The size of the step is 0.2 mm.

The curved face portion 31 is provided with an outer circumferential edge face 31t that has been formed in the direction intersecting the holding portion 32 at the border with the holding portion 32. In the outer circumferential edge face 31t, the side of the holding portion 32 is enlarged to the outside compared to the side of the curved face portion 31. As described above, the lens thickness is 2.99 mm, the height of the outer circumferential edge face 31t is 2.44 mm, and the inclination angle of the outer circumferential edge face 31t is 5.2 degrees (the side of the holding portion 32 is enlarged to the outside compared to the side of the top face of the curved face portion 31).

Following is a description of operation of the outer circumferential edge face 31. In the present embodiment, the frame body cover portions 47 (see FIGS. 9A and 9B) are formed that cover the frame body portion 40 disposed between adjacent curved face portions 31 and cover the space between adjacent curved face portions 31. The frame body cover portions 47 are formed using black resin (for example, silicone resin), and because they cover the space between adjacent curved face portions 31, it is possible to improve the contrast ratio and waterproofing of the display apparatus 1.

If the outer circumferential edge face 31t is not present (when the curved face of the curved face portion 31 is extended as-is to the holding portion 32), when the frame body cover portion 47 is formed, there is a risk that the frame body cover portion 47 (black silicone resin) will ride up on the curved face portion 31. Also, the border between the curved face portion 31 and the frame body cover portion 47 becomes unclear, so that control of the height and surface flatness of the frame body cover portion 47 becomes difficult. When the frame body cover portion 47 rides up on the curved face portion 31 there is a risk that light from the lens inner portion (the surface mount-type light-emitting device 10) will be blocked.

When the outer circumferential edge face 31t is not present, moreover, unevenness occurs in the surface of the frame body cover portion 47, so that there is a risk that water drainage (in particular, drainage of rainwater in the case of outdoor installation) will be insufficient. When water drainage is insufficient, not only is there an adverse effect on the drive circuits 70 and so forth disposed inside of the case 50, there is also a risk of decreasing visibility due to collection of moisture on the surface of the lens unit 30 (the curved face portion 31), for example.

In the display apparatus 1 (the lens unit 30) according to the present embodiment, because there is the outer circumferential edge face 31t, it is possible to eliminate the aforementioned problems regarding display properties, reliability, and so forth.

As described above, in the display apparatus 1 according to the present embodiment, the holding portion 32 of the lens unit 30 is provided with the resin injection inlet 34 applied to filling of translucent resin, and the resin discharge outlet 35 that has been formed corresponding to the resin injection inlet 34. Accordingly, in the display apparatus 1, it is possible to easily and precisely form the filled resin portion 38.

Also, the curved face portion 31 is provided with the outer circumferential edge face 31t that has been formed in the direction intersecting the holding portion 32 at the border with the holding portion 32. Accordingly, in the display apparatus 1, because the frame body cover portion 47 is regulated by the outer circumferential edge face 31t, it is possible to prevent the frame body cover portion 47 from being stacked on the curved face portion 31, and so distinguishing (display precision) between curved face portions 31 by the frame body cover portions 47 can be improved.

Also, in the outer circumferential edge face 31t, the side of the holding portion 32 is enlarged to the outside relative to the side of the top face of the curved face portion 31. Accordingly, in the display apparatus 1, the frame body cover portion 47 is reliably regulated by the outer circumferential edge face 31t so that the curved face portion 31 can be precisely defined, and thus it is possible to further improve display precision. Also, when forming the lens units 30 and the frame body portion 40 by a double molding method, it is possible to improve separation from the injection molding die.

FIGS. 6A and 6B show an enlarged view of a partial state of a lens array module formed by double molding lens units and a frame body portion, applied to the display apparatus according to the embodiment of the present invention, where FIG. 6A is a plan view, and FIG. 6B is a cross-sectional view at arrows B-B in FIG. 6A.

FIGS. 7A and 7B illustrate the overall configuration of the lens array module shown in FIGS. 6A and 6B, where FIG. 7A is a plan view, and FIG. 7B is a see-through side view showing relevant portions when viewed in a see-through manner from the direction of arrow B in FIG. 7A.

The frame body portion 40 is configured into a lens array module 40m in which the lens units 30 are disposed in the form of a dot matrix having 8 rows×8 columns, the entire matrix constituting the lens array module 40m. That is, the frame body portion 40 is disposed surrounding the lens units 30, thus fixing the position of the lens units 30. Also, 64 lens units 30 are incorporated in the lens array module 40m to constitute a lens array 40L. The surface mount-type light-emitting devices 10 that have been mounted to the wiring substrate 20 are disposed corresponding to the respective lens units 30 (see FIGS. 8A and 8B).

The lens array module 40m is formed using a double molding method. Accordingly, after molding the lens units 30 (first side) with translucent resin, the frame body portion 40 (second side) can be molded with black resin, so the precise lens array module 40 can be efficiently formed. That is, the lens units 30 and the frame body portion 40 (the lens array module 40m) can be precisely and easily formed, so the lens array 40L in which the lens units 30 have been precisely disposed can be formed.

Note that if the lens units 30 and the frame body portion 40 are separately formed, and the lens units 30 are affixed to the frame body portion 40 with adhesive, there is a risk that the adhesive will stick to the resin injection inlet 34, the resin discharge outlet 35, and so forth, so that a defective shape occurs. Also, when the adhesive sticks to the resin injection inlet 34 and the resin discharge outlet 35, the openings become plugged, so that the adhesive cannot be injected/discharged. That is, it is not possible to fill the appropriate amount of resin, and as a result the filled resin portion 38 has a defective shape.

Accordingly, by double molding the lens units 30 and the frame body portion 40, it is possible to precisely and productively form the lens array module 40m. Also, as necessary, it is possible to separately form the lens units 30 and the frame body portion 40, and then inlay the lens units 30 into the frame body portion 40 to form a single body.

The frame body portion 40 is provided with a resin collection groove 41 that collects the translucent resin that has been discharged from the resin discharge outlet 35 when forming the filled resin portion 38 (see FIGS. 8A and 8B). Accordingly, in the display apparatus 1, translucent resin that overflowed from the resin discharge outlet 35 when the filled resin portion 38 was formed is separated from the lens units 30 and collected in the resin collection groove 41, so it is possible to prevent such resin from adversely affecting the optical properties of the lens units 30.

The frame body portion 40 that forms the lens array module 40m is made to have light-blocking properties in order to block light between adjacent surface mount-type light-emitting devices 10 and filled resin portions 38, and for example, is formed of a black resin such as black (carbon black) polycarbonate resin or black silicone resin. The polycarbonate resin is excellent with respect to transparency, impact resistance, heat resistance, flame resistance, and so forth, and therefore can be used to improve weather resistance, and therefore is particularly effective when the display apparatus 1 will be installed outdoors.

The resin collection groove 41, for example, is configured with a width of 1 mm and a depth of 1 mm, but is acceptable if configured with an optimal size such that translucent resin that has been injected in order to form the filled resin portion 38 will not overflow.

Also, the frame body portion 40 is provided with a resin collection hole 42 formed deeper than the resin collection groove 41 and in communication with the resin collection groove 41. Accordingly, in the display apparatus 1, even if an excess of the translucent resin that forms the filled resin portion 38 has been supplied, the translucent resin is collected in the resin collection hole 42 via the resin collection groove 41, so it is possible to reliably prevent the translucent resin from impairing the optical properties of the lens units 30 (particularly the curved face portions 31).

On the back face side, the lens array module 40m (frame body portion 40) is provided with an engaging protrusion 45 that operates as a positioning means and engaging means when attaching to the wiring substrate 20. In the present embodiment, it is possible to attach a set of four lens array modules 40m (lens arrays 40L) to the wiring substrate 20. That is, 64×4=256 surface mount type light-emitting devices 10 and lens units 30 are disposed in the entire display apparatus 1.

As described above, in the display apparatus according to the present embodiment, the holding portion 32 is provided with the skirt portion 36 extended to the side of the wiring substrate 20 and contacting the frame body portion 40. Accordingly, in the display apparatus 1, it is possible to easily and precisely form the lens units 30 and the frame body portion 40, and it is possible to easily and precisely form the filled resin portions 38.

Also, the skirt portion 36 grows larger to the outside further to the side of the wiring substrate 20. Accordingly, in the display apparatus 1, it is possible to precisely form the frame body portion 40 and the skirt portion 36.

The lens array module 40m (frame body portion 40) is provided with a screw hole 40s for attaching to the wiring substrate 20. That is, the lens array module 40m is attached to the wiring substrate 20 using a screw (M2.6).

Also, the lens array module 40m (frame body portion 40) is provided with a pass-through groove 40h that passes through the frame body portion 40. The pass-through groove 40h is disposed so as to correspond to the wiring pattern formed on the wiring substrate 20 (a land pattern corresponding to a pass-through hole 21 (see FIGS. 8A and 8B) where interconnecting wiring is implemented by passing through both faces of the wiring substrate 20). Accordingly, the wiring pattern that has been formed on the wiring substrate 20 is precisely recognized via the pass-through groove 40h, so the position of the lens array module 40m can be precisely matched with the wiring substrate 20.

Note that the pass-through groove 40h is likewise filled with the synthetic resin (translucent resin) that forms the filled resin portion 38 so that a filled resin groove portion 38h is formed (see FIGS. 8A and 8B), and thus the wiring substrate 20 is not exposed and so there is no problem with waterproofing.

FIGS. 8A and 8B illustrate a state in which, in a production process of the display apparatus according to the embodiment of the present invention, a wiring substrate to which a lens array module has been attached is attached to a case, and a filling resin portion has been formed by filling a space between the surface mount-type light-emitting devices and the lens units with translucent resin, where FIG. 8A is a schematic side view that schematically shows the state of a side face, and FIG. 8B is an enlarged cross-sectional view that shows an enlarged view of the area of reference sign B in FIG. 8A.

First, the surface mount-type light-emitting devices 10 are mounted to the surface (display face 20d) of the wiring substrate 20, and the drive circuits 70 are mounted to a back face 20c of the wiring substrate 20. Then, the lens array module 40m (lens array 40L) is attached to the display face 20d, with the surface mount-type light-emitting devices 10 and the lens units 30 corresponding to each other.

The frame body portion 40 is configured into the lens array module 40m (lens array 40L) in which the lens units 30 have been disposed in the form of a dot matrix, and the lens array module 40m (lens array 40L) is attached to the wiring substrate 20 as an attachment unit. Accordingly, in the display apparatus 1, strength of the frame body portion 40 is insured, positioning precision of the lens units 30 relative to the surface mount-type light-emitting devices 10 is insured, and thus it is possible to improve reliability and display precision.

That is, because this attachment to the wiring substrate 20 is performed with the display face of the display apparatus 1 divided by a plurality (for example, the above-described set of four) of the lens array modules 40m (lens arrays 40L), the occurrence of a mismatch in the positions of the surface mount-type light-emitting devices 10 and the lens units 30 relative to the wiring substrate 20 is suppressed, thus insuring positional precision, so display precision can be improved.

As described above, the display apparatus 1 is provided with the drive circuits 70 that drive the surface mount-type light-emitting devices 10, and the drive circuits 70 are mounted to the back face 20c on the opposite side as the display face 20d of the wiring substrate 20 where the surface mount-type light-emitting devices 10 have been disposed. Accordingly, in the display apparatus 1, it is easy to mount (connect) the drive circuits 70 that drive the surface mount-type light-emitting devices 10, and thus reliability can be improved. Note that the surface mount-type light-emitting devices 10 that have been disposed on the display face 20d of the wiring substrate 20 and the drive circuits 70 that have been disposed on the back face 20c are connected to each other via the pass-through holes 21 that have been formed in advance in the wiring substrate 20.

The wiring pattern on both faces of the wiring substrate 20 is connected via the pass-through holes 21, so the surface mount-type light-emitting devices 10 that have been disposed on the display face 20d and the drive circuits 70 that have been disposed on the back face 20c are compactly connected.

As described above, the lens array module 40m (lens array 40L) is fixed by screwing to the wiring substrate 20, or is fixed by adhesive (for example, silicone resin) that has been applied to the wiring substrate 20. The lens array module 40m is screwed to the case 50.

The space between the surface mount-type light-emitting devices 10 and the lens units 30 (curved face portions 31) is filled with synthetic resin (translucent resin) to form the filled resin portions 38. That is, the display apparatus 1 is provided with the filled resin portions 38 filled with synthetic resin (translucent resin) between the surface mount-type light-emitting devices 10 and the curved face portions 31 (lens units 30). Accordingly, in the display apparatus 1, the environmental tolerance (reliability) of the surface mount-type light-emitting devices 10 is improved, and by eliminating an air layer between the surface mount-type light-emitting devices 10 and the lens units 30, it is possible to improve light transmission (light intensity, i.e., display properties, in front of the display apparatus 1). Excess synthetic resin supplied when forming the filled resin portions 38 flows out to the resin collection groove 41 and forms a groove filled resin portion 38r.

The synthetic resin is desirably a translucent resin. That is, by using translucent resin for the synthetic resin, it is possible to easily realize the necessary luminous intensity. In the description below, reference may be made to only one of synthetic resin or translucent resin.

As shown in FIGS. 5A to 5C, the filled resin portions 38 are formed by injecting translucent resin (translucent silicone resin) via the resin injection inlet 34 using an injector (potting). The resin discharge outlet 35 is disposed at a position opposing the resin injection inlet 34, so it is possible to fill with translucent resin while eliminating air.

In an injection time of about 1 second, the translucent resin that has been injected from the resin injection inlet 34 overflows (is discharged) from the resin discharge outlet 35, so the translucent resin injection time is set to about 1 second. The translucent resin that has been discharged from the resin discharge outlet 35 can be absorbed into the resin collection groove 41 and the resin collection hole 42. Accordingly, excess translucent resin does not stick to the lens units 30 (curved face portions 31).

It is desired that the translucent resin that forms the filled resin portions 38 fits well with lens units 30, the surface mount-type light-emitting devices 10, the wiring substrate 20, and the frame body portion 40. Specifically, epoxy resin, silicone resin, or the like is preferred. Moreover, in order to further increase the fitting, the translucent resin is injected after applying a primer to the surface of the package portion 12 of the surface mount-type light-emitting devices 10, the surface (display face 20d) of the wiring substrate 20, the frame body portion 40, and so forth. Thus, the fitting improves.

The synthetic resin (translucent resin) used when forming the filled resin portions 38 is also filled in the pass-through groove 40h formed in the frame body portion 40. Injection is performed in the same manner as injection of the synthetic resin into the resin injection inlet 34. Accordingly, a groove filled resin portion 38h is formed in the pass-through groove 40h.

For example, resin hardening and air bubble removal is performed by leaving the injected translucent resin at room temperature for 24 hours, for example. Afterward, this resin is hardened by performing a heat treatment with hardening conditions of 80° C., 45 minutes, thus forming the filled resin portions 38.

As described above, the inside face 31r (see FIGS. 5A to 5C) opposing the wiring substrate 20 of the curved face portion 31 has a convex shape bulging toward the wiring substrate 20. Accordingly, in the display apparatus 1, when the space between the surface mount-type light-emitting device 10 and the curved face portion 31 has been filled with the synthetic resin (translucent resin), it is possible to prevent air bubbles from remaining in the filled resin portion 38.

In the above description, the drive circuits 70 are disposed on the back face 20c, but if the layout is changed, it is also possible to dispose the drive circuits 70 on the display face 20d. In such a case, it is desirable that the drive circuits 70 are disposed only on either one of those faces.

That is, in the display apparatus 1 according to the present invention, it is desirable that the drive circuits 70 that drive the surface mount-type light-emitting devices 10 are provided, and the drive circuits 70 are mounted only on either one of the display face 20d of the wiring substrate 20 where the surface mount-type light-emitting devices 10 have been disposed or the back face 20c on the opposite side.

Accordingly, in the display apparatus 1 according to the present invention, when the drive circuits 70 are disposed only on the display face 20d of the wiring substrate 20, it is possible to simultaneously mount the surface mount-type light-emitting devices 10 and the drive circuits 70 to the wiring substrate 20, thus improving productivity. Also, in the display apparatus according to the present invention, when the drive circuits 70 are disposed only on the back face 20c of the wiring substrate 20, it is possible to form the wiring substrate 20 to match the outer shape of the display apparatus 1, and to dispose the surface mount-type light-emitting devices 10 so as to match the outer shape of the display apparatus 1.

FIGS. 9A and 9B illustrate a state in which, in a production process of the display apparatus according to the embodiment of the present invention, a frame body cover portion has been formed, where FIG. 9A is a schematic side view that schematically shows the state of a side face, and FIG. 9B is an enlarged cross-sectional view that shows an enlarged view of the area of reference sign B in FIG. 9A.

After the filled resin portion 38 is formed, the frame body cover portions 47 that cover the frame body portion 40 are formed. That is, the display apparatus 1 is provided with the frame body cover portions 47 that cover the frame body portion 40. Accordingly, in the display apparatus 1, the frame body cover portions 47 cover the frame body portion 40, so it is possible to cover the border of the lens units 30 and the frame body portion 40 with the frame body cover portions 47, and therefore it is possible to improve display precision due to making clear the distinction between lens units 30 (the curved face portions 31), and possible to improve environmental tolerance (waterproofing).

The material applied to the frame body cover portions 47 is desired to fit well with the lens units 30, the frame body portion 40, the case 50, and so forth. Also, in order to protect the drive circuit 70, flexibility and weather resistance are requested. Accordingly, as the material of the frame body cover portions 47, it is possible to apply at least one type selected from among epoxy resin, urethane resin, and silicon resin, for example. Also, in order to improve contrast, a dark-colored dye or pigment having a dark color such as black (carbon black) may be included in the resin that forms the frame body cover portions 47. Furthermore, a heat-conducting member may be included with the object of improving heat conductance. In the present embodiment, the frame body cover portions 47 are formed of silicone resin containing black (carbon black).

Also, in the present embodiment, the frame body cover portions 47 cover the holding portion 32. Accordingly, in the display apparatus 1, because the frame body cover portions 47 cover both the frame body portion 40 and the holding portion 32, it is possible to further improve display precision due to making clear the distinction between the lens units 30 (the curved face portions 31), and possible to further improve environmental tolerance.

The covering resin that forms the frame body cover portions 47 is supplied in the space between the lens units 30 (the outer circumferential edge faces 31t) so as to cover the holding portion 32 and the frame body portion 40. After the covering resin is filled between adjacent outer circumferential edge faces 31t, the covering resin is hardened by leaving that resin at room temperature for 24 hours, for example. Afterward, the resin is hardened by performing a heat treatment with hardening conditions of 80° C., 45 minutes, thus forming the frame body cover portions 47.

The frame body cover portions 47 cover the holding portion 32, so the resin injection inlet 34 and the resin discharge outlet 35 can be plugged. Accordingly, for example, it is possible to prevent water from mixing into pinholes or the like that have been accidentally formed in the filled resin portions 38. Also, the filled resin portions 38 and the frame body cover portions 47 are formed so as to stack on each other, so accidentally formed pinholes can be plugged, and thus waterproofing improves.

As described above, in the display apparatus 1 according to the present embodiment, the wiring substrate 20, on which the surface mount-type light-emitting devices 10, the drive circuits 70, and the lens array modules 40m (the lens arrays 40L) have been mounted, is attached to the case 50.

It is preferable that the case 50 (external case) fits well with the covering resin (for example, silicone resin) that forms the frame body cover portions 47. From the viewpoint of ease of molding, the material of the case 50 is preferred to be polycarbonate resin, ABS resin, epoxy resin, phenol resin, or the like. In the present embodiment, the case 50 is formed with polycarbonate resin.

The case 50 is a member that mechanically protects from outside the surface mount-type light-emitting devices 10 arranged in the form of a matrix on the display face 20d of the wiring substrate 20, the drive circuits 70 mounted on the back face 20c of the wiring substrate 20, the wiring substrate 20, and so forth, and therefore the case 50 can be formed at a desired size.

FIGS. 10A and 10B illustrate a state in which, in a production process of the display apparatus according to the embodiment of the present invention, a visor portion has been attached, where FIG. 10A is a schematic side view that schematically shows the state of a side face, and FIG. 10B is an enlarged cross-sectional view that shows an enlarged view of the area of reference sign B in FIG. 10A.

Visor portions 60 are disposed corresponding to the respective surface mount-type light-emitting devices 10 (the lens units 30 and the frame body portion 40). The visor portions 60 are disposed corresponding to the row direction of the frame body portion 40 (the lens array modules 40m) and the frame body cover portions 47. That is, as shown in FIGS. 1A to 1C, 16 visor portions 60 are disposed corresponding to the 16 rows of surface mount-type light-emitting devices 10 provided in the display apparatus 1. The reason that the visor portions 60 are disposed in the row direction is in order to prevent a reduction in visibility due to incident light (external light) such as sunlight from above in the vertical direction. Note that the visor portions 60 preferably are colored with a color such as black in order to improve light-blocking efficiency, and black (carbon black) polycarbonate resin can be applied as the visor portions 60.

The height H1 of the visor portions 60 is set to 10 mm, and the height H2 of the visor portion 60 disposed uppermost in the vertical direction is set to 12.5 mm. The height of the visor portions 60 is designed so as to insure a viewing angle in the vertical direction of 10 degrees, and such that direct sunlight is prevented as much as possible from being directly incident on the surface mount-type light-emitting devices 10. Accordingly, the display apparatus 1 can have both visibility and light-blocking properties.

Also, for water elimination, the visor portions 60 are provided with water removal portions 61 with a height of 1 mm and a width of 4 mm between the visor portions 60 and the case 50 (the frame body cover portions 47). The visor portions 60 are attached to the case 50 with screws (not shown). Specifically, the visor portions 60 are fixed with screws to the case 50 via the frame body portion 40 on the side of the back face 20c of the wiring substrate 20.

Polycarbonate is a resin material that exhibits high physical properties with respect to transparency, impact resistance, heat resistance, flame resistance, and so forth. Also, polycarbonate has low cost relative to its superior physical properties, and therefore even in the present embodiment, as described above, black (carbon black) polycarbonate resin can be variously applied, such as to the frame body portion 40, the case 50, and the visor portions 60. Below, a modified example for polycarbonate will be described.

A UV-reflecting agent may be mixed into the polycarbonate. In this case, it is possible to prevent deterioration of members (such as the frame body portion 40, the case 50, and the visor portions 60) due to UV rays included in sunlight, so the reliability of the display apparatus 1 can be improved.

Resin containing a UV-reflecting agent is formed by mixing and dispersing the UV-reflecting agent in polycarbonate resin or silicone resin used as translucent resin material, and converting the result to resin. As the UV-reflecting agent, it is possible to apply fine powder of silicon oxide and fine powder of a metal oxide such as aluminum oxide, zinc oxide, titanium oxide, or magnesium oxide.

An infrared-reflecting agent may further be applied in the polycarbonate. As an infrared-reflecting agent, TiO₂ powder is formed by heating titanium hydroxide in a Grade 4 titanium saline solution, and passing this through a sieve. The TiO₂ powder is mixed into silicone resin and agitated to obtain a slurry of resin containing an infrared-reflecting member. The infrared-reflecting member can be applied to the case 50, the wiring substrate 20, and the visor portions 60, excepting the opening portion of the surface mount-type light-emitting devices 10.

It has been confirmed that in the display apparatus 1 in which a UV-reflecting agent and an infrared-reflecting agent have been applied, temperature increases are suppressed, and contaminants such as air bubbles are not included, so excellent reliability and optical properties can be realized.

Below, the superiority of the display apparatus 1 according to the present embodiment over a conventional example will be described.

In the display apparatus 1, even if the number of disposed surface mount-type light-emitting devices 10 is increased, the surface mount-type light-emitting devices 10 can be mounted to the display face 20d of the wiring substrate 20, and the drive circuits 70 mounted to the back face 20c of the wiring substrate 20. Thus, long wires are not needed, so mounting (connection) can be performed with reduced wire length and greater reliability than in the case of a conventional example.

Also, in the display apparatus 1, the surface mount-type light-emitting devices 10 are adopted instead of conventionally-adopted molded-type LED lamps (lead protruding-type LED lamps). Accordingly, even when the number of semiconductor light-emitting elements (semiconductor light-emitting element chips) is increased and the semiconductor light-emitting elements 14r, 14g, and 14b for three colors are adopted in order to perform multi-color display, because these can be incorporated into a single surface mount-type light-emitting device 10, it is possible to mount the surface mount-type light-emitting devices 10 to the display face 20d of the wiring substrate 20, and mount the drive circuits 70 to the back face 20c.

With a conventional molded-type LED lamps, a lead frame comes through the back face of the wiring substrate, so it is necessary to use these by folding or cutting the lead frame. Therefore, it is difficult to mount the drive circuits 70 on the face on the opposite side as the face where the molded-type LED lamps have been mounted.

On the other hand, in the display apparatus 1, the surface mount-type light-emitting devices 10 are connected to the display face 20d of the wiring substrate 20, and the drive circuits 70 are connected to the back face 20c, so the light-emitting device wiring substrate and the driver circuit wiring substrate that are necessary in the conventional example are made a single body. Accordingly, the number of wires can be reduced, and thus it is possible to improve reliability.

Also, in the display apparatus 1, it is possible to adopt a desired arrangement for the wiring pattern formed in the wiring substrate 20, so it is possible to adopt a desired arrangement for the surface mount-type light-emitting devices 10, and so the display apparatus 1 is capable of a variety of types of display.

Also, because the surface mount-type light-emitting devices 10, the lens unit 30, the filled resin portions 38, the frame body portion 40 (the lens array modules 40m) and the frame body cover portions 47 are adopted as constituent elements, the amount of resin used can be greatly reduced compared to a conventional example, so the display apparatus 1 can be lightened, and also it is possible to improve environmental tolerance and improve reliability.

The display apparatus 1 according to the present invention, for example, has the following advantages indicated by (a), (b), and (c) in comparison to a display apparatus in which molded-type LED lamps are applied. (a) It is possible to reduce the amount of synthetic resin used because the case thickness is reduced. (b) The mass of the surface mount-type light-emitting devices can be made about 10% of the mass of conventional molded-type LED lamps. (c) Wiring substrates and wiring patterns (land patterns) can be reduced.

Also, it is necessary to improve display properties by disposing black resin for waterproofing and contrast between the molded-type LED lamps mounted to the wiring substrate. In comparison to the amount of black resin for waterproofing and contrast used in this case, the amount used can be reduced to about 67%.

The present invention may be embodied in various other forms without departing from the spirit or essential characteristics thereof. The embodiments disclosed in this application are to be considered in all respects as illustrative and not limiting. The scope of the invention is indicated by the appended claims rather than by the foregoing description, and all modifications or changes that come within the meaning and range of equivalency of the claims are intended to be embraced therein.

### REFERENCE SIGNS LIST

1 display apparatus
10 surface mount-type light-emitting device
11 external terminal
12 package portion
13 concave portion
14r, 14g, 14b semiconductor light-emitting element
15 translucent resin portion
16 black portion
20 wiring substrate
20d display face
20c back face
21 pass-through hole
30 lens unit
31 curved face portion
31r inside face
31t outer circumferential edge face
32 holding portion
32g gate-corresponding portion
32s step
34 resin injection inlet
35 resin discharge outlet
36 skirt portion
36s surface
38 filled resin portion
40 frame body portion
40L lens array
40m lens array module
41 resin collection groove
42 resin collection hole
45 engaging protrusion
47 frame body cover portions
50 case
51 engaging portion
60 visor portion
61 water removal portion
70 drive circuit

What is claimed is:

1. A display apparatus comprising:
a surface mount-type light-emitting device having an external terminal for surface mounting;
a wiring substrate where the surface mount-type light-emitting device has been mounted;
a lens unit disposed opposing the surface mount-type light-emitting device; and
a frame body portion disposed surrounding the lens unit.

2. The display apparatus according to claim 1,
wherein the lens unit includes a curved face portion having a curved face, and a holding portion that is extended from the curved face portion to the frame body portion and holds the curved face portion.

3. The display apparatus according to claim 2,
further comprising a filled resin portion formed by filling a space between the surface mount-type light-emitting device and the curved face portion with synthetic resin.

4. The display apparatus according to claim 3,
wherein the synthetic resin is a translucent resin.

5. The display apparatus according to claim 3,
wherein the holding portion includes an injection inlet applied to filling of the synthetic resin, and a resin discharge outlet formed opposing the resin injection inlet.

6. The display apparatus according to claim 5,
wherein the frame body portion includes a resin collection groove that collects the synthetic resin that has been discharged from the resin discharge outlet.

7. The display apparatus according to claim 6,
wherein the frame body portion includes a resin collection hole formed in communication with the resin collection groove and deeper than the resin collection groove.

8. The display apparatus according to claim 2,
wherein the holding portion includes a skirt portion that is extended to the side of the wiring substrate and contacts the frame body portion.

9. The display apparatus according to claim 8,
wherein the skirt portion grows larger to the outside toward the side of the wiring substrate.

10. The display apparatus according to claim 2,
further comprising a frame body cover portion that covers the frame body portion.

11. The display apparatus according to claim 10,
wherein the frame body cover portion covers the holding portion.

12. The display apparatus according to claim 11,
wherein the curved face portion includes an outer circumferential edge face formed in a direction intersecting the holding portion at a border with the holding portion.

13. The display apparatus according to claim 12,
wherein in the outer circumferential edge face, the side of the holding portion is enlarged to the outside.

14. The display apparatus according to claim 11,
wherein the lens unit is formed by injection molding, and includes a gate-corresponding portion that is disposed at an outside position where the holding portion is extended and corresponds to a gate portion of an injection molding die, and a step formed between the gate-corresponding portion and the holding portion.

15. The display apparatus according to claim 3,
wherein an inside face opposing the wiring substrate of the curved face portion is formed in a convex shape bulging toward the wiring substrate.

16. The display apparatus according to claim 1,
wherein the frame body portion is configured into a lens array module in which lens units are disposed in the form of a dot matrix, and the lens array module is attached to the wiring substrate as an attachment unit.

17. The display apparatus according to claim 16,
wherein the lens array module is formed by a double molding method.

18. The display apparatus according to claim 1,
further comprising a drive circuit that drives the surface mount-type light-emitting device, the drive circuit being mounted only on either one of a display face of the wiring substrate where the mount-type light-emitting devices have been disposed or a back face on the opposite side.

19. The display apparatus according to claim 1,
wherein the surface mount-type light-emitting device includes a plurality of semiconductor light-emitting elements whose emitted light colors differ from each other.
